(19) United States
(12) Patent Application Publication
(10) Pub. No.: US 2008/0012578 A1
(43) Pub. Date: Jan. 17, 2008

(54) System for detecting molecular structure and events

(75) Inventor: Richard Campbell, Portland, OR (US)

Correspondence Address: CHERNOFF, VILHAUER, MCCLUNG & STENZEL, 1600 ODS TOWER, 601 SW SECOND AVENUE, PORTLAND, OR, 97204-3157, US

(73) Assignee: Cascade Microtech, Inc.

(21) Appl. No.: 11/710,151

(22) Filed: Feb. 22, 2007

Related U.S. Application Data
(60) Provisional application No. 60/830,878, filed on Jul. 14, 2006.

(51) Int. Cl. G01R 27/26

(52) U.S. Cl. 324/633

(57) ABSTRACT

The molecular structure of a medium and the occurrence of events effecting the molecular structure of a medium are determined by measuring the effect on the resonant frequency and/or the dissipated current of an oscillating electric field when a sample of a medium under test occupies a portion of the region of the field.

### CROSS-REFERENCE TO RELATED APPLICATIONS

This application claims the benefit of U.S. Provisional Application No. 60/830,878, filed Jul. 14, 2006.

### BACKGROUND OF THE INVENTION

The present invention relates to systems for detecting the molecular structure of media and events related to a medium's molecular structure and, more particularly, to systems and methods utilizing dielectric spectroscopy to detect molecular structure and events related thereto.

The dielectric properties of a material are the result of the interaction of an external electromagnetic field with the molecules of the material. Referring to FIG. 1, the dielectric constant or relative permittivity of a medium is, typically, a complex value comprising a real part (ε′) 20 which quantifies the part of the external electric field's energy that is stored in the medium and an imaginary part, the loss factor (ε″) 22, which quantifies the part of the field's energy that is dissipated. The dielectric properties of a medium are the result of a plurality of mechanisms, each of which may variously contribute to the permittivity of the medium at certain frequencies of the external electric field. The molecular structure of the medium is causally polarized in response to the external electric field so polarization lags a change in the electric field. In addition, time is required for the molecular structure of the medium to respond in the manner dictated by each mechanism and, therefore, each mechanism, typically, has a sharply defined cut-off or relaxation frequency above which the mechanism has little or no effect on the permittivity. Typically, the relaxation frequency of a mechanism is accompanied by a corresponding peak in the loss factor.

Dipole polarization, the rotation of a molecular dipole in the presence of an electric field, substantially effects permittivity at frequencies up to a relaxation frequency which typically occurs in the microwave frequency range. Ionic conduction, the motion of ions in the direction of an applied electric field, introduces losses in the system and, in combination with dipole polarization, substantially determines relative permittivity at lower frequencies. As the frequency of the external field increases, the effects of these slower mechanisms diminish and the dielectric properties are increasingly determined by faster mechanisms. Electronic polarization, displacement of the nucleus of an atom with respect to the surrounding electrons, and atomic polarization, deformation of adjacent positive and negative ions in the presence of an electric field, are often dominant mechanisms effecting the permittivity of dry solids at microwave frequencies and above. Any change in the molecular structure of the medium will be reflected in a change in the effect produced by one or more of the mechanisms that determine the dielectric properties of the medium. For example, as milk sours the molecular structure changes producing a change in the dielectric properties of the milk. Dielectric spectroscopy, the measurement of the dielectric properties of a medium as a function of frequency, is used to identify a medium and determine when molecular events, such as chemical binding, have occurred altering the molecular structure of the medium and its dielectric properties.

Referring to FIG. 2, a dielectric spectroscopic system 40 typically comprises a network analyzer 42 and a test fixture 44 to retain a sample 46 of a medium-under-test during testing. The test fixture commonly comprises a sample holder arranged to retain the sample in a gap in a transmission line, such as a stripline, a microstrip or a waveguide; within a resonant cavity or in contact with a coaxial probe. A source 48 transmits a incident signal 50, typically in the microwave frequency range, along a signal path 52, typically, a coaxial cable or a transmission line, to the fixture where the incident signal is either directly or indirectly electromagnetically coupled to the sample. A portion of the incident signal is reflected 54 as a result of the impedance mismatch represented by the sample and another portion 56 of the incident signal is transmitted by the sample. As the incident signal illuminates the sample, the signal is modulated by the dielectric properties of the sample producing unique reflected and transmitted signals at the frequency of the incident signal. At least one of the reflected and transmitted signals is transmitted to a detector 58 in the network analyzer.

The network analyzer, which may comprise a vector network analyzer or a scalar network analyzer, typically includes the source, the detector, and a display 62 that are controlled by a data processor 64 which may be included in or separate from the network analyzer. The network analyzer measures the amplitude or the amplitude and the phase of the incident signal and the reflected and/or transmitted signals. For example, the network analyzer may be used to measure a one-port return loss response signal (an S₁₁ response) or scattering parameter. The frequency at which the amplitude of the return loss (S₁₁) signal is minimized is highly correlated to the real part of the sample's complex permittivity or dielectric constant and the Q-factor, a ratio of the frequency at which S₁₁ is minimized to the half power bandwidth of the resonant fixture, is correlated to the imaginary part of the permittivity. Measurement of one or both of these parameters provides a basis for identifying the molecular structure of the medium comprising the sample and detecting molecular events, such as molecular binding, occurring in the sample and altering the molecular structure of the medium.

While dielectric spectroscopy has several advantages over other methods for determining the molecular structure of materials and detecting related events, the cost of the network analyzer can be prohibitive and limits deployment of the process. What is desired, therefore, is a less expensive system and method for detecting dielectric properties of a medium, including media of biological origin, and detecting changes in those properties.

### BRIEF DESCRIPTION OF THE DRAWINGS

FIG. 1 is an graphical illustration of frequency and the operation of various mechanisms effecting permittivity.

FIG. 2 is a block diagram of a dielectric spectroscope.

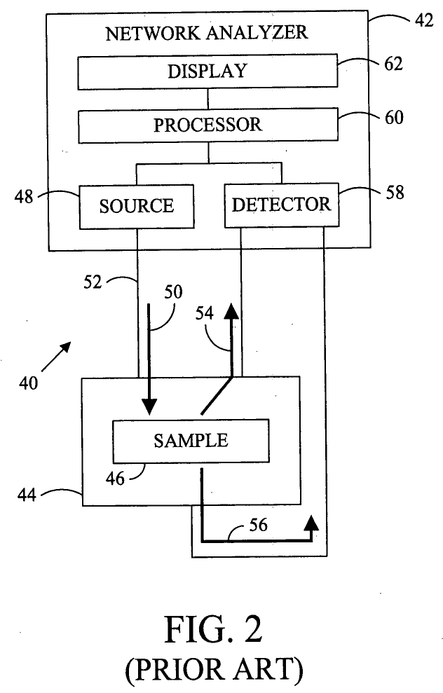

FIG. 3 is a schematic diagram of a first embodiment of a system for detecting a molecular structure of a medium and events related thereto.

FIG. 4 is a schematic diagram of a second embodiment of a system for detecting a molecular structure of a medium and events related thereto.

FIG. 5 is a perspective view of an exemplary holder for securing a sample in an electric field region of a resonator.

### DETAILED DESCRIPTION OF PREFERRED EMBODIMENTS

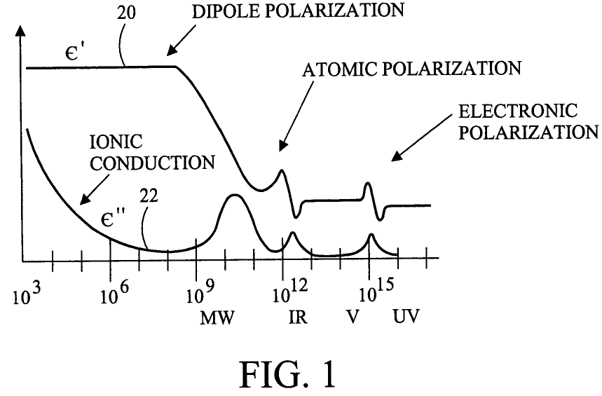

Dielectric spectroscopy comprises the measurement of the dielectric properties of a medium as a function of the frequency of an external electric field incident on a sample of the medium. Referring to FIG. 1, the dielectric constant or relative permittivity of a medium is, typically, a complex value comprising a real part (ε′) 20 which quantifies the part of the external electric field's energy that is stored in the medium and an imaginary part, the loss factor (ε″) 22, which quantifies the part of the field's energy that is dissipated. The dielectric properties of the medium are the result of polarization of various elements of the molecular structure of the medium by their interaction with the electric field. Since the polarization is caused by the electric field, the polarization effects lag changes in the field. Further, because permittivity is affected by a plurality of mechanisms, each operating on different elements of the molecular structure, and since the different elements of the molecular structure cannot instantaneously align with the electric field, the permittivity of a medium is frequency dependent. For example, dipole polarization, the rotation of a molecular dipole in the presence of an electric field, substantially effects permittivity at frequencies up to a relaxation frequency which commonly occurs in the microwave frequency range. Ionic conduction, the motion of ions in the direction of an applied electric field, introduces losses in the system and, in combination with dipole polarization, substantially determines permittivity at lower frequencies. As the frequency of the external field increases, the effects of slower mechanisms diminish and the dielectric properties are increasingly determined by faster mechanisms. Electronic polarization, displacement of the nucleus of an atom with respect to the surrounding electrons, and atomic polarization, deformation of adjacent positive and negative ions in the presence of an electric field, are often dominant mechanisms effecting the permittivity of dry solids at microwave frequencies and above. As illustrated by FIG. 1, each mechanism has a cut-off or relaxation frequency above which the effect of the mechanism is substantially diminished and which is typically accompanied by a corresponding peak in the loss factor for the medium.

Dielectric spectroscopy, the determination of the permittivity of a medium as a function of the frequency of an external electric field, is typically performed by subjecting a sample of the medium to microwave radiation and analyzing one or more scattering parameters related to the signals reflected by or transmitted from the sample. Typically, the microwave signal is generated and analyzed with a network analyzer. A network analyzer is an expensive instrument and the cost of a network analyzer limits the deployment of dielectric spectroscopy even though the method has advantages over other methods for identifying materials and events related to their molecular structure. The present inventor realized that the permittivity of a medium is determined by its molecular structure and that the permittivity of a sample of a medium located in the electric field region of a resonant circuit effects the resonant frequency of the circuit. Moreover, frequency can be measured with instrumentation that is substantially less expensive than a network analyzer. The inventor reasoned that differences, if any, in the permittivity and, therefore, the molecular structure of two samples, whether the result of a molecular event or otherwise, can be less expensively determined by measuring the resonant frequency or the loss current of a resonant circuit while alternately locating a sample of a medium-under-test and a sample of a known medium in an electric field region of the circuit.

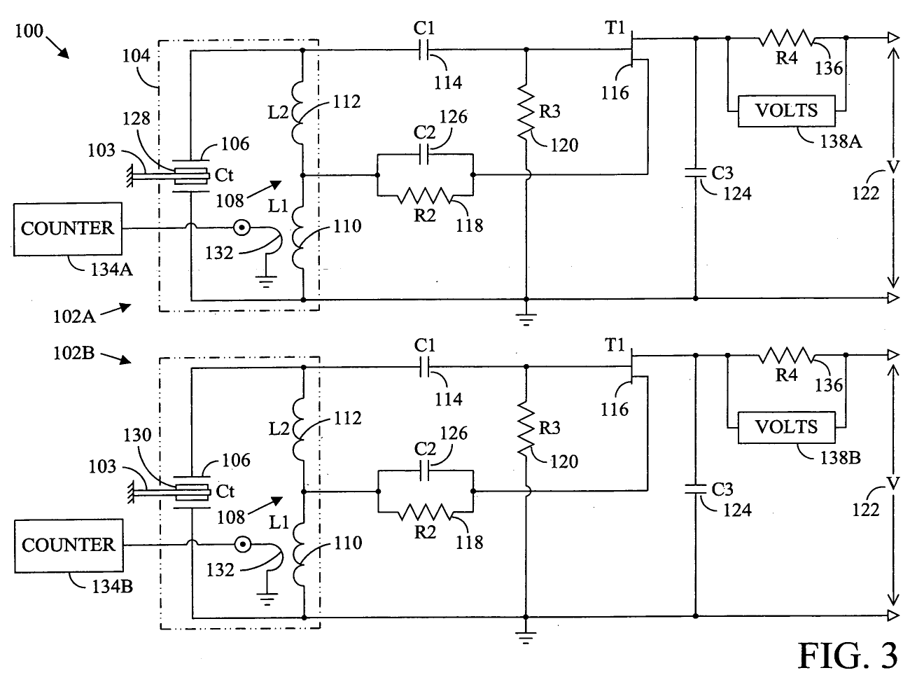

Referring to FIG. 3, an apparatus 100 for evaluating the permittivity of a medium-under-test and detecting molecular events comprises an oscillator 102A including a sample holder 103 enabling a user to secure a sample of a medium in an electric field region of a resonating tank circuit 104. In the embodiment depicted in FIG. 3, the oscillator is a Hartley oscillator comprising a tank circuit including a tuned, tank capacitor, Ct, 106 and a tapped inductor 108 comprising a first inductor, L1, 110 and a second inductor, L2, 112. A coupling capacitor, C1, 114 connects the tank capacitor and the inductor to the base of a transistor, T1, 116 and prevents a base to emitter short circuit through the resistor, R2, 118 and the second inductor, L2. The bias of the transistor is determined by the values of the resistor, R3, 120; the emitter-to-base resistance of the transistor; the DC resistance of the second inductor, L2; and the resistor, R2, 118. The capacitor, C3, 124 permits the alternating current signal at the collector of the transistor, T1, to bypass the DC voltage source 122 and the capacitor, C2, 126 in parallel with the resistor R2 permits the alternating current signal at the emitter to bypass the resistor R2 without dissipating as heat in the resistor.

When a DC voltage 122 is applied to the circuit, current will flow through the first inductor 110 and through the resistor, R2, to the emitter of the transistor, T1. The current will flow between the emitter and the collector and back to the DC voltage source. Oscillation of the tank circuit is initiated by the surge of current through the first inductor which induces a voltage in the second inductor, L2. This induced voltage makes the junction of the tank capacitor, second inductor and coupling capacitor, C1, positive. The positive potential is coupled to the base of the transistor through the coupling capacitor, C1, increasing the forward bias of the transistor and causing an increase in collector current. The increasing collector current increases the current flowing through the first inductor and the transistor's emitter. The increasing current in the first inductor also increases the energy stored in the electrostatic field of the tank capacitor and the positive potential at the coupling capacitor, C1. The increasingly positive potential at the coupling capacitor further increases the forward bias of the transistor.

After an initial charging period, the tank capacitor, Ct, is charged to the potential across the first and second inductors and the rate of change of current flow in the first inductor decreases. The reduction in the rate of change of current flow in the first inductor, L1, causes a reduction in the voltage induced in the second inductor, L2. The positive potential across the tank circuit begins to decrease and the tank capacitor, Ct, starts discharging the energy stored in its electrical field through the first and second inductors. The current flow through the first and second inductors produces a reduction in the forward bias of the transistor and a reduction in the collector-emitter current of the transistor. When the potential across the tank circuit decreases to zero, energy stored in the electrostatic field of the tank capacitor has been transferred to and stored in the magnetic fields of the inductors, L1, L2.

However, when the current flow from the tank capacitor ends, the magnetic field around the inductor collapses momentarily producing a negative potential across the second inductor and causing the tank capacitor to begin to charge with opposite polarity. The negative potential at the coupling capacitor, C1, is coupled to the base of the transistor opposing its forward bias. When the junction of tank capacitor, second inductor and coupling capacitor reaches its maximum negative voltage the magnetic field of the inductor will have collapsed, the electrostatic field in the tank capacitor, Ct, will be restored and the oscillator will have completed three-fourths of a cycle.

The charged tank capacitor will begin to discharge energy stored in the electric field, decreasing the negative potential at the junction of the tank circuit and the coupling capacitor, C1. The voltage opposing the forward bias of the transistor decreases permitting an increase in emitter current and an increase in the current flowing through the first inductor. The increase in current in the first inductor provides additional energy to the tank circuit to replace energy dissipated by the system. When the tank capacitor is fully discharged, the oscillator will have completed one cycle and, if the energy dissipated in the circuit is replaced, will repeat the cycle again and again, outputting an alternating voltage at the resonant frequency of the tank circuit.

The electric field of the tank capacitor will oscillate at the resonant frequency of the tank circuit which is a function of the respective values of the inductor, L, and the tank capacitor, Ct. For an ideal tank circuit, without resistance, the resonant frequency equals:

$${f}_{res} = \frac{1}{2 π \sqrt{LCt}} \qquad ( 1 )$$

### However, the value of capacitor and, therefore, the resonant frequency of the tank circuit is related to the permittivity of a dielectric medium located in the region of the electric field proximate the capacitor.

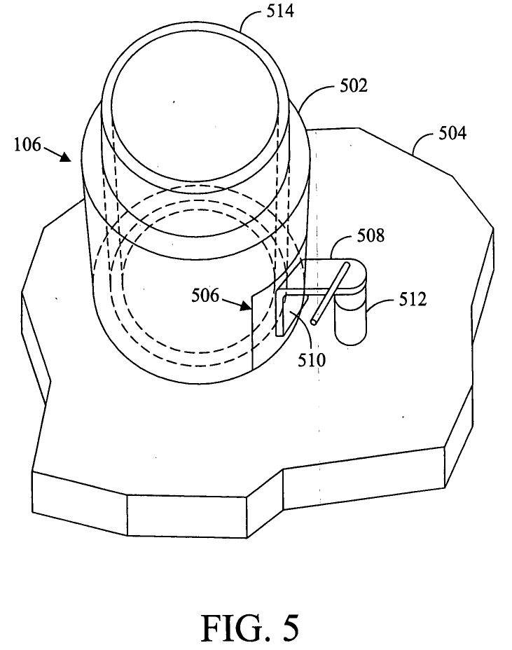

As illustrated schematically in FIG. 3, in the apparatus 100, a sample 128 of a medium, which may be a medium of biological origin, is secured in the electric field region of the tank capacitor 106 of the oscillator 102A by the sample holder 103. Referring also to FIG. 5, an exemplary tank capacitor comprises a hollow tubular first plate 502 which is mounted to a base 504. A window 506 is cut in the wall of the first plate. A second plate 508, supported on the base by an insulating post 512 and insulated from the base and the first plate, includes a portion 510 that is aligned with the window in the first plate. A sample of a medium to be tested is retained for testing in a sample holder comprising a tubular vessel 506 of non-conductive material, such as glass, that fits within the inner diameter of the first plate. The sample of the medium under test is secured in the region of the electric field that is created by energizing the first and second plates.

A transducer 132 connected to a frequency counter 134A enables measurement of the resonant frequency of operation of the tank circuit as it is effected by the presence of the sample. The resonant frequency is related to the real part, ε′, of the complex permittivity. Likewise, the current flowing in the current sense resistor, R4, 136, measurable with a voltmeter 138, reflects the current dissipated in the system and is related to the imaginary portion of the permittivity, the loss factor, ε″. A difference between a known medium and an unknown medium-under-test can be detected by respectively placing samples of the media in the electric field of the oscillator and measuring the resonant frequencies of operation and/or the loss currents during respective tests. If the resonant frequencies are the same and/or if there is no a difference between the loss currents, the medium-under-test and the known medium are the same. On the other hand, if the molecular structure of the samples are different, as a result of a molecular event or otherwise, the relative permittivity of the two samples and, therefore, the resonant frequencies and/or the loss currents will be unequal for the two tests. The identity of an unknown medium may be determined by comparing the resonant frequency or loss current obtained by testing the unknown medium with known resonant frequencies and/or loss currents produced by testing a plurality of known media in the same or substantially identical oscillators.

The apparatus 100 comprises two substantially identical oscillators 102A, 102B enabling simultaneous testing of a sample of an unknown medium 128 and a sample of a known medium 130 and simultaneous measurement of the resonant frequencies and loss currents with, respectively, the frequency counters 134A and 134B and voltmeters 138A and 138B.

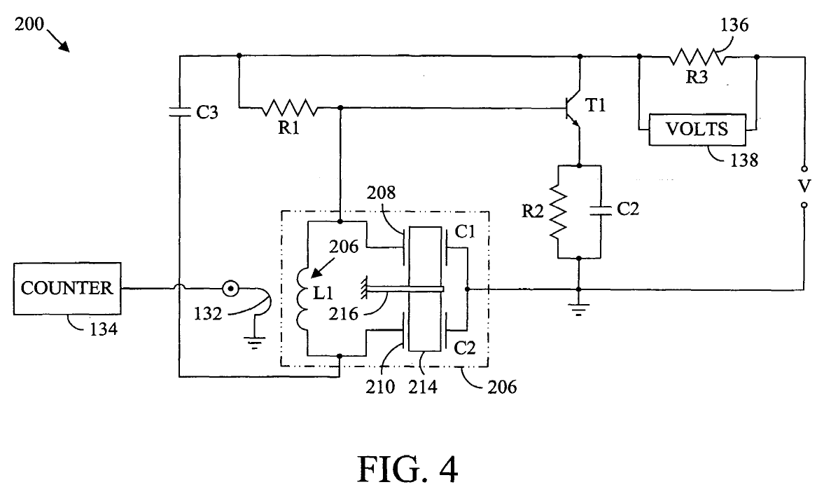

While the embodiment illustrated in FIG. 3, incorporates a Hartley oscillator, the oscillating electric field can be produced with other types of oscillators, such as a Colpitts oscillator or a Pierce oscillator, or a microwave cavity. Referring to FIG. 4, the apparatus 200 for detecting molecular structure and events utilizes a Colpitts oscillator. The Colpitts oscillator is similar to the Hartley oscillator but the tank circuit 204 comprises a single inductor 206 and a pair of capacitors 208, 210. The resonant frequency of oscillation of the Colpitts oscillator equals:

$${f}_{res} = \frac{1}{2 π \sqrt{L 1 \cdot ( \frac{C 1 \cdot C 2}{C 1 + C 2} )}} \qquad ( 2 )$$

The resonant frequency of a Colpitts oscillator can be varied by varying the value of the inductance or the value of the capacitance of the tank circuit. A sample of a medium-under-test 214 secured in the region of the electric field of the oscillator by a sample holder 216 alters the value of the capacitance and the resonant frequency of the tank circuit. A frequency counter 134 connected to a transducer 132 outputs the resonant frequency at which the oscillator operates and a voltmeter 138 connected in parallel with the sense resistor R3, 136 measures the replacement current.

A difference between the molecular structure of an unknown medium-under-test and a known medium can be determined by comparing the resonant frequency and/or the loss current of a resonant circuit when operated with respective samples of the media located in an electric field region of the circuit. The resonant frequency and the loss current can be measured with instrumentation that is much less expensive than a network analyzer which is typically employed when performing dielectric spectroscopy.

The detailed description, above, sets forth numerous specific details to provide a thorough understanding of the present invention. However, those skilled in the art will appreciate that the present invention may be practiced without these specific details. In other instances, well known methods, procedures, components, and circuitry have not been described in detail to avoid obscuring the present invention.

All the references cited herein are incorporated by reference.

The terms and expressions that have been employed in the foregoing specification are used as terms of description and not of limitation, and there is no intention, in the use of such terms and expressions, of excluding equivalents of the features shown and described or portions thereof, it being recognized that the scope of the invention is defined and limited only by the claims that follow.

I (We) claim:

1. An apparatus for detecting a dielectric property of a medium under test, said apparatus comprising:
(a) an oscillator operable at a resonant frequency and capable of generating an electric field;
(b) a sample holder for securing a sample of said medium under test in a region of said electric field; and
(c) an instrument for detecting at least one of said resonant frequency and a loss current of said oscillator.

2. The apparatus for detecting a dielectric property of a medium under test of claim 1 wherein said instrument comprises a frequency counter for detecting said resonant frequency of said oscillator.

3. The apparatus for detecting a dielectric property of a medium under test of claim 1 wherein said instrument for detecting a loss current comprises a meter for measuring a replacement current for a current dissipated by said oscillator during operation at said resonant frequency.

4. The apparatus of claim 1 wherein said oscillator is a Hartley oscillator.

5. The apparatus of claim 1 wherein said oscillator is a Colpitts oscillator.

6. An apparatus for detecting a dielectric property of a medium under test, said apparatus comprising:
(a) a first oscillator operable at a resonant frequency and capable of generating a first electric field;
(b) a first sample holder for securing a sample of said medium under test in a region of said first electric field;
(c) a second oscillator operable at a resonant frequency and capable of generating a second electric field, said second oscillator being substantially identical to said first oscillator;
(d) a second sample holder for securing a sample of a known medium in a region of said second electric field; and
(e) an instrument for detecting at least one of said resonant frequencies of said first and said second oscillators and a loss current of each of said first and said second oscillators.

7. The apparatus for detecting a dielectric property of a medium under test of claim 6 wherein said instrument comprises a frequency counter for detecting said resonant frequencies of said first and said second oscillators.

8. The apparatus for detecting a dielectric property of a medium under test of claim 6 wherein said instrument for detecting a loss current of each of said first and said second oscillators comprises a meter for measuring a replacement current for a current dissipated by respectively by said first oscillator and said second oscillator during operation said respective oscillator at said respective resonant frequency.

9. A method for detecting a dielectric property of a medium under test, said method comprising the steps of:
(a) determining a first resonant frequency of oscillation of an electric field when a portion of a region of said electric field is occupied by a sample of said medium under test;
(b) determining a second resonant frequency of oscillation of said electric field when a portion of said region of said electric field is occupied by a sample of a second medium; and
(c) comparing said first resonant frequency to said second resonant frequency.

10. The method for detecting a dielectric property of a medium under test of claim 9 wherein at least one said medium under test and said second medium comprises a medium of biological origin.

11. A method for detecting a dielectric property of a medium under test, said method comprising the steps of:
(a) determining a magnitude of a first current dissipated during resonant oscillation of an electric field when a portion of a region of said electric field is occupied by a sample of said medium under test;
(b) determining a magnitude of a second current dissipated during resonant oscillation of said electric field when a portion of said region of said electric field is occupied by a sample of a second medium; and
(c) comparing said first current to said second current.

12. The method for detecting a dielectric property of a medium under test of claim 11 wherein at least one said medium under test and said second medium comprises a medium of biological origin.
